(19) United States
(12) Patent Application Publication
(10) Pub. No.: US 2015/0000972 A1
(43) Pub. Date: Jan. 1, 2015

(54) MODULAR ELECTRICAL JUNCTION BOX AND METHOD OF USE

(71) Applicant: Fred Mayer, Wellington, FL (US)

(72) Inventor: Fred Mayer, Wellington, FL (US)

(21) Appl. No.: 14/264,156

(22) Filed: Apr. 29, 2014

Related U.S. Application Data
(60) Provisional application No. 61/839,529, filed on Jun. 26, 2013.

(51) Int. Cl. H05K 5/02; H05K 13/00

(52) U.S. Cl. CPC H05K 5/0217; H05K 13/0023
USPC 174/560; 29/825

(57) ABSTRACT

An electrical junction box assembly is disclosed that includes an electrical junction box housing having a plurality of junction box walls defining an interior region, and at least one aperture defined by at least one of the plurality of junction box walls, the aperture adapted to receive at least one electrical wire. The electrical junction box assembly further includes an inner housing disposed within the interior region of the electrical junction box housing and segmenting the interior region into a substantially-enclosed cavity and an open-face cavity. The inner housing is substantially adjacent to one of the plurality of junction box walls such that the electrical wire received into the electrical junction box housing via the aperture is disposed only within the substantially-enclosed cavity and not within the open-face cavity.

### CROSS-REFERENCE TO RELATED APPLICATION

This application claims priority to U.S. Provisional Patent Application No. 61/839,529 filed Jun. 26, 2013, the entirety of which is incorporated by reference.

### FIELD OF THE INVENTION

The present invention relates generally to an electrical junction box, and more particularly relates to an electrical junction box assembly with a primary junction box housing and an inner housing that substantially encloses any electrical wires for preventing unsafe electrical exposure during the wiring process and providing an uncomplicated, safe, and cost-efficient junction box and method of use.

### BACKGROUND OF THE INVENTION

Current practice in electrically wiring a commercial or a residential building or structure includes routing electrical wires from a circuit breaker through one or more electrical units disposed throughout the building. Electrical units can be an electrical outlet, a light switch, a light fixture or the like, attached to a corresponding electrical junction box. To install electrical units throughout an unfinished building, electricians affix a plurality of electrical junction boxes to wall studs prior to installing drywall and then route wires from the circuit breaker to each of the electrical junction boxes. Electricians may leave these exposed wires within the electrical junction boxes, which are open-faced boxes, until they are ready to complete wiring each electrical unit within the corresponding electrical junction box. When electricians are ready to wire the electrical units, the multitude of wires within the electrical junction box must be tediously attached to the multitude of electrical contacts on the electrical unit. This process can be very time-consuming and, therefore, increase associated labor costs.

There is an increasing desire of many property owners to perform their own wiring of electrical switches, electrical outlets, and other electrical units within the building. As novice electricians, there is a danger that such property owners may cause an electrical short and/or physical injury to themselves or others. This danger increases proportionally with the complexity of the wiring processes and apparatuses used. Additionally, it is particularly undesirable for novice electricians to leave wires exposed to the outside environment as novice electricians may not be as cautious of exposed wiring as professionally trained and experienced electricians.

Electrical wiring can result in a tangled web of wires jammed within the electrical junction box. This also results in a safety hazard and increases the difficulty of the wiring process. Moreover, multiple bends within a wire can wear the wire down over time.

Removing an installed electrical junction box from a finished building can require breaking through the drywall in order to access a fastener for unfastening the electrical junction box. This results in wasteful damage to the finished drywall that will require an additional step of repairing the damage to the drywall after the electrical junction box is removed.

Therefore, a need exists to overcome the problems with the prior art as discussed above.

### SUMMARY OF THE INVENTION

The invention provides an electrical junction box assembly and method of use that overcomes the hereinafore-mentioned disadvantages of the heretofore-known devices and methods of this general type and that substantially encloses any electrical wires for preventing unsafe electrical exposure during the wiring process.

With the foregoing and other objects in view, there is provided, in accordance with the invention, an electrical junction box assembly, including an electrical junction box housing having a plurality of junction box walls defining an interior region, and at least one aperture defined by at least one of the plurality of junction box walls, the at least one aperture adapted to receive at least one electrical wire. The electrical junction box assembly further includes an inner housing disposed within the interior region of the electrical junction box housing. The inner housing includes a plurality of inner housing walls; a plurality electrical contacts operably configured to couple with a corresponding electrical modular unit; and the inner housing segments the interior region into: a substantially-enclosed cavity, the substantially-enclosed cavity defined by the plurality of inner housing walls; and an open-face cavity, the open-face cavity being a remainder of the interior region. The inner housing is also substantially adjacent to one of the plurality of junction box walls such that the at least one electrical wire received into the electrical junction box housing through the at least one aperture is disposed only within the substantially-enclosed cavity and not within the open-face cavity.

In accordance with another feature, the inner housing is substantially adjacent to a top one of the plurality of junction box walls; and the at least one aperture is defined by the top one of the plurality of junction box walls.

In accordance with another feature, the electrical junction box housing and the inner housing are integral with one another.

In accordance with a further feature of the present invention, the top one of the plurality of junction box walls is integral with a top one of the plurality of inner housing walls.

In accordance with a further feature of the present invention, an embodiment of the present invention also includes a second aperture defined by the at least one of the plurality of junction box walls, wherein the at least one aperture is operably configured to receive the at least one electrical wire from a circuit breaker into the inner housing and the second aperture is operably configured to route a second electrical wire from within the inner housing out to an external electrical device.

In accordance with another feature of the present invention, the inner housing abuts the at least one of the plurality of junction box walls that defines the at least one aperture.

In accordance with yet another feature of the present invention, the inner housing includes a wire retention device adapted to retain the at least one electrical wire within the inner housing for electrically coupling the at least one electrical wire to the corresponding electrical modular unit.

In accordance with a further feature of the present invention, the inner housing includes a wire retention device adapted to slideably receive the at least one electrical wire through the at least one aperture, and frictionally retain the at least one electrical wire within the inner housing for electrically coupling the at least one electrical wire to the corresponding electrical modular unit.

In accordance with a further feature of the present invention, the wire retention device includes a resilient member.

In accordance with another feature of the present invention, at least one of the plurality of junction box walls defines a second aperture operable as passageway from the open-face cavity to a wall stud in an external environment, the second aperture adapted to receive a fastener therethrough for fastening the electrical junction box housing to the wall stud laterally abutting the electrical junction box housing.

In accordance with another feature of the present invention, the corresponding electrical modular unit includes an electrical conducting member and a front one of the plurality of inner housing walls defines at least one opening adapted to receive the electrical conducting member for electrically coupling the at least one electrical wire to the corresponding electrical modular unit.

In accordance with yet another feature, the corresponding electrical modular unit is formed as an electrical outlet adapted to electrically couple to the at least one electrical wire within the inner housing.

In accordance with another feature, the corresponding electrical modular unit includes an electrical conducting member and is formed as an electrical outlet adapted to electrically couple to the at least one electrical wire within the inner housing and mechanically couple to the inner housing by engaging the electrical conducting member of the electrical outlet to an opening defined by a front one of the plurality of inner housing walls.

In accordance with yet another feature of the present invention, the electrical conducting member is formed as a projection.

In accordance with another feature of the present invention, the corresponding electrical modular unit includes an electrical conducting member and is formed as an electrical switch adapted to electrically couple to the at least one electrical wire within the inner housing.

In accordance with the present invention, an embodiment of the present invention includes a method for preparing electrical wiring within an electrical junction box without exposing any electrical wires therein to an external environment, where the method includes providing an electrical junction box assembly including: an electrical junction box housing having a plurality of junction box walls defining an interior region, and at least one aperture defined by at least one of the plurality of junction box walls, and an inner housing disposed within the interior region of the electrical junction box housing and segmenting the interior region into: a substantially-enclosed cavity, and an open-face cavity, the substantially-enclosed cavity defined by a plurality of inner housing walls forming the inner housing and the open-face cavity being a remainder of the interior region. The method further includes inserting at least one electrical wire that is electrically coupled to a circuit breaker into the at least one aperture such that the at least one electrical wire is disposed only within the substantially-enclosed cavity and not within the open-face cavity.

In accordance with another feature, an embodiment of the present invention also includes slideably inserting the at least one electrical wire within a wire retention device disposed within the inner housing; and securing the at least one electrical wire to the wire retention device.

In accordance with yet another feature, an embodiment of the present invention includes inserting the at least one electrical wire from the external environment into the inner housing through the at least one aperture in a singular direction to engage a wire retention device disposed within the inner housing; and securing the at least one electrical wire to the wire retention device.

In accordance with a further feature of the present invention, the method further includes receiving the at least one electrical wire from the circuit breaker into the inner housing through the at least one aperture; and routing a second electrical wire from the inner housing to an external electrical device via a second aperture.

In accordance with a further feature of the present invention, the method further includes securing the electrical junction box housing to a wall stud laterally abutting the electrical junction box by moving a fastener from within the open-face cavity through a third aperture defined by at least one of the plurality of junction box walls and fastening the fastener to the wall stud.

Although the invention is illustrated and described herein as embodied in an electrical junction box and method, it is, nevertheless, not intended to be limited to the details shown because various modifications and structural changes may be made therein without departing from the spirit of the invention and within the scope and range of equivalents of the claims. Additionally, well-known elements of exemplary embodiments of the invention will not be described in detail or will be omitted so as not to obscure the relevant details of the invention.

Other features that are considered as characteristic for the invention are set forth in the appended claims. As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one of ordinary skill in the art to variously employ the present invention in virtually any appropriately detailed structure. Further, the terms and phrases used herein are not intended to be limiting; but rather, to provide an understandable description of the invention. While the specification concludes with claims defining the features of the invention that are regarded as novel, it is believed that the invention will be better understood from a consideration of the following description in conjunction with the drawing figures, in which like reference numerals are carried forward. The figures of the drawings are not drawn to scale.

Before the present invention is disclosed and described, it is to be understood that the terminology used herein is for the purpose of describing particular embodiments only and is not intended to be limiting. The terms “a” or “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The term “coupled,” as used herein, is defined as connected, although not necessarily directly, and not necessarily mechanically.

As used herein, the terms “about” or “approximately” apply to all numeric values, whether or not explicitly indicated. These terms generally refer to a range of numbers that one of skill in the art would consider equivalent to the recited values (i.e., having the same function or result). In many instances these terms may include numbers that are rounded to the nearest significant figure.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and explain various principles and advantages all in accordance with the present invention.

FIG. 1 is a perspective view an electrical junction box assembly in accordance with the present invention;

FIG. 2 is an enlarged, perspective view of an inner housing of the electrical junction box assembly, originally introduced in FIG. 1, in accordance with the present invention;

FIG. 3 is a fragmentary and enlarged, elevational, partially cross-sectional view of a spring-based wire retention device in accordance with an embodiment of the present invention;

FIG. 4 is a fragmentary and enlarged, elevation, partially cross-sectional view of a combination spring-based and screw-based wire retention device in accordance with an embodiment of the present invention;

FIG. 5 is a schematic diagram of an electrical circuit including a plurality of electrically coupled junction box assembles for a light switch, a light fixture, and an electrical outlet in accordance with an embodiment of the present invention;

FIG. 6 is a schematic diagram of another exemplary embodiment of an electrical circuit including a plurality of electrically coupled junction box assemblies for a light switch, a light fixture, and an electrical outlet in accordance with an embodiment of the present invention; and

FIG. 7 is a process flow diagram illustrating a method of preparing electrical wiring in accordance with the present invention.

### DETAILED DESCRIPTION

While the specification concludes with claims defining the features of the invention that are regarded as novel, it is believed that the invention will be better understood from a consideration of the following description in conjunction with the drawing figures, in which like reference numerals are carried forward. It is to be understood that the disclosed embodiments are merely exemplary of the invention, which can be embodied in various forms.

The present invention provides a novel and efficient electrical junction box assembly that provides for safe, time-saving, and cost-efficient electrical wiring that substantially encloses electrical wiring within the electrical junction box assembly that would otherwise be exposed to the external environment through the open-face of the junction box during the wiring process. Embodiments of the invention provide an electrical junction assembly including an electrical junction box housing and an inner housing that is substantially enclosed. In addition, embodiments of the invention provide a method of safely and more cost-effectively preparing electrical wiring within an electrical junction box without exposing any electrical wires therein to the outside environment.

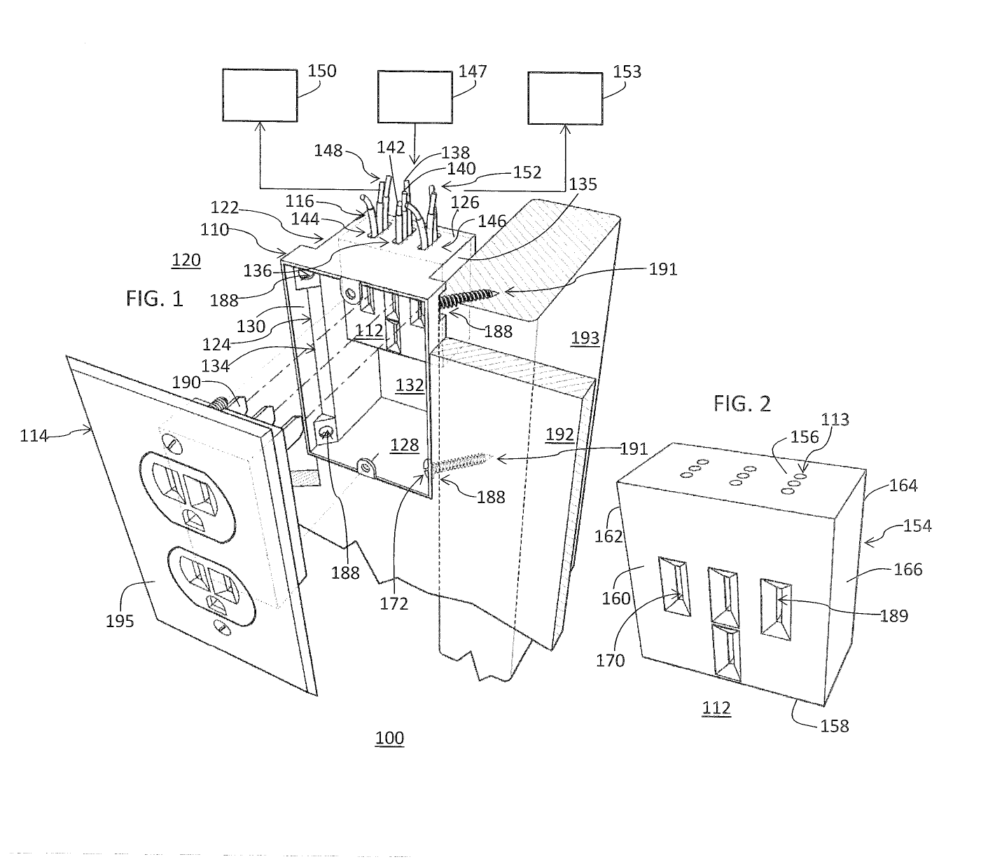

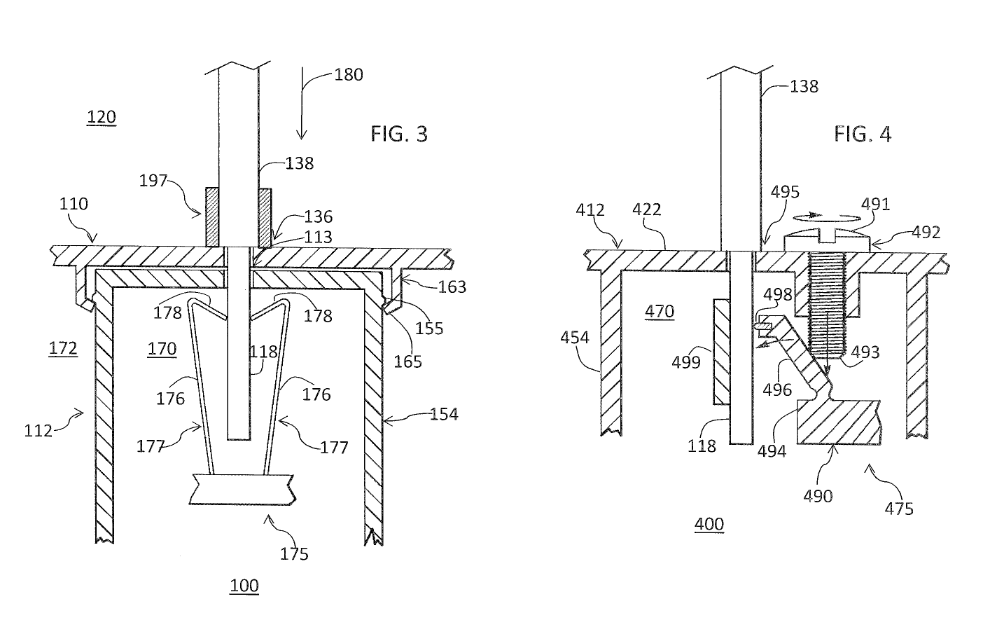

Referring now to FIG. 1, one embodiment of the present invention is shown in a perspective view. FIG. 1 shows several advantageous features of the present invention, but, as will be described below, the invention can be provided in several shapes, sizes, combinations of features and components, and varying numbers and functions of the components. The first example of an electrical junction box assembly 100, as shown in FIG. 1, includes an electrical junction box housing 110, an inner housing 112, and an electrical modular unit 114, also referred to herein as a corresponding electrical modular unit 114. As can be readily appreciated, the configuration of the inner housing 112, being adapted to receive electrical wires 116 directly into the inner housing 112 and substantially enclose the electrical wires 116 within the electrical junction box housing 110, provides for a safe and convenient wiring process by eliminating exposure of electrical wires 116 and bare electrical terminals 118 (FIG. 3) to an external environment 120.

The electrical junction box housing 110 includes a plurality of junction box walls 122 having a top junction box wall 126 and a bottom junction box wall 128 opposite and parallel to the top junction box wall 126. The electrical junction box housing 110 can also be seen having a first 130, a second 132, and a third junction box sidewall 135 extending between and situated substantially perpendicularly to the top junction box wall 126 and the bottom junction box wall 128. The plurality of junction box walls 122 collectively define an interior region 124 of the electrical junction box housing 110. As used herein, the “interior region” is defined as an area within the exterior walls of a housing, where when the housing has an open face, the interior region is further delimited by an imaginary plane extending across an outer rim of the housing at the open face. An outer plane of the interior region 124 defines an open-face 134 of the electrical junction box housing 110, the open-face 134 being in fluid communication with the interior region 124 and the external environment 120. As used herein, the “external environment” is intended to indicate the environment outside of the electrical junction box housing 110 and outside of the interior region 124 of the electrical junction box housing 110. The open-face 134 of the electrical junction box housing 110 exposes portions of the interior region 124 to the external environment 120, as can be readily seen in FIG. 1. Any loose electrical wiring exposed via the open-face 134 would present a safety hazard, if not for the inner housing 112, as explained in more detail below.

At least one of the plurality of junction box walls 122 can further define a first aperture 136. The first aperture 136 is adapted to receive at least one electrical wire 116 into the inner housing 112 from a circuit breaker 147. Providing a junction box with pre-formed apertures eliminates the need for a drill and knowledge of how to use the drill to properly form and position apertures in the junction box. In one embodiment, the first aperture 136 can be sized and configured to receive three electrical wires 116 into the electrical junction box housing 110, namely a first electrical wire 138, a second electrical wire 140, and a third electrical wire 142. The first electrical wire 138 can be a “hot” wire, which, as is known in the art, is a wire that provides a current source to an electrical unit. The second electrical wire 140 can be a neutral wire, which provides a return path for the current provided by the hot wire. The third electrical wire 142 can be a ground wire. The first aperture 136 can be defined by the top junction box wall 126, as illustrated in FIG. 1. Allowing insertion of the electrical wires 138, 140, and 142 through the top junction box wall 126 can reduce the number of turns required to complete the wiring in some configurations. The top junction box wall 126 can further define a second aperture 144 and a third aperture 146. The second aperture 144 is operably configured to route a second set of electrical wires 148 from within the inner housing 112 out to an external electrical device 150, such as, for example, a light fixture. The third aperture 146 is operably configured to route a third set of electrical wires 152 from within the inner housing 112 out to yet another external electrical device 153, such as, for example, an electrical outlet. Providing the electrical junction box housing 110 with three separate apertures 136, 144, and 146 formed therein and dedicated to particular incoming and outgoing electrical lines provides organization and structure to the multitude of electrical wires 116 that may be routed through the electrical junction box housing 110.

Referring now primarily to FIGS. 1-2, the inner housing 112 is disposed within the interior region 124 of the electrical junction box housing 110. The inner housing 112 includes a plurality of inner housing walls 154 having a top inner housing wall 156, a bottom inner housing wall 158 opposite and parallel to the top inner housing wall 156. The inner housing 112 can also be seen having a first 160, a second 162, a third 164, and a fourth inner housing sidewall 166 extending between and situated substantially perpendicularly to the top inner housing wall 156 and the bottom inner housing wall 158. In one embodiment, the plurality of inner housing walls 154 can be integral with one another. In another embodiment, the plurality of inner housing walls 154 can be integral with the electrical junction box housing 110. The inner housing 112 segments the interior region 124 of the electrical junction box housing 110 into a substantially-enclosed cavity 170 and an open-face cavity 172. The substantially-enclosed cavity 170 is within the inner housing 112 and is defined by the plurality of inner housing walls 154 that form the inner housing 112. As used herein, the term “substantially-enclosed cavity” is defined as a contiguous hollow area that is within walls forming a housing, which may have one or more slits or small apertures defined by one or more of the housing walls sized to receive plugs, e.g., electrical conducting members 190, from the modular unit 114. Those of skill in the art can appreciate that the size of said plugs are the standardized amounts typically associated with plugs. The open-face cavity 172 is a remainder of the contiguous hollow area within the interior region 124, which is not the contiguous hollow area of the substantially-enclosed cavity 170. As used herein, the term “open-face cavity” is defined as a contiguous hollow area that is within walls forming a housing that has an open-face 134, the open-face cavity also being delimited by an imaginary plane extending across and defined by a peripheral rim of the housing at the open-face 134.

The inner housing 112 can be substantially adjacent to one of the plurality of junction box walls 122, such as the top inner housing wall 156, such that electrical wires 116 received into the electrical junction box housing 110 via apertures 136, 144, 146 are disposed only within the substantially-enclosed cavity 170 and not within the open-face cavity 172. Advantageously, this feature eliminates exposure of any electrical wires 116 to the external environment 120, which reduces risk of injury, fire, or electrical shorts. Said another way, the open-face cavity 172 is free from any wiring or electronic cables that could possibly injure novice electricians. The inner housing 112 can abut a one of the plurality of junction box walls 122 that defines the apertures 136, 144, and 146 adapted to receive electrical wires 116 therein. In one embodiment, the inner housing 112 can abut the top inner housing wall 156. In another embodiment, the inner housing 112 and the electrical junction box housing 110 are integral with one another. Fabricating the electrical junction box assembly 100 such that the inner housing 112 and the electrical junction box housing 110 are integral may reduce manufacturing costs and complexity. In yet another embodiment, the top inner housing wall 156 and the top junction box wall 126 are integral with one another. The inner housing 112 can further include a plurality of inner housing apertures 113 defined by one of the plurality of inner housing walls 154. In the exemplary embodiment, the plurality of inner housing apertures 113 are defined by the top inner housing wall 156. The inner housing 112 may include a plurality of electrical contacts (now shown) operably configured to couple with the corresponding electrical modular unit 114 and transfer electricity from the wiring 116 to said modular unit 114. As used herein, an “electrical contact” is an electrical circuit component operably configured to allow electrical current to pass therethrough.

Referring still primarily to FIGS. 1-2, the plurality of junction box walls 122 can define a fourth aperture 188 operable as a passageway from the open-face cavity 172 to a wall stud 193 in the external environment 120. The fourth aperture 188 is adapted to receive a fastener 191 therethrough from an inside of the electrical junction box housing 110 for fastening the electrical junction box housing 110 to the wall stud 193, which laterally abuts the electrical junction box housing 110. Users can unfasten the fastener 191 from the inside of the electrical junction box housing 110. Advantageously, this feature allows the electrical junction box assembly 100 to be removed without damaging the drywall 192, which is typically constructed around the electrical junction box assembly 100. In the current art, fasteners 191 are typically disposed behind drywall 192 such that fasteners 191 are not accessible without breaking through drywall 192 to access the fasteners 191.

The first inner housing wall 160 may define a plurality of openings 189 for allowing a physical and an electrical coupling between corresponding electrical wires 116 in the inner housing 112 and the electrical modular unit 114. In the exemplary embodiment, there are four openings 189, however, there can be provided any number of openings 189 defined by the first inner housing wall 160. For example, in another embodiment, there can be provided only three openings 189. The electrical modular unit 114 includes a plurality of electrical conducting members 190. The plurality of electrical conducting members 190 can be formed as a plug, or other projecting body. Each of the plurality of openings 189 is adapted to receive a corresponding one of the plurality of electrical conducting members 190 into the substantially-enclosed cavity 170 of the inner housing 112 for electrically coupling corresponding electrical wires 116 to the electrical modular unit 114. The electrical modular unit 114 can further include a cover plate 195 sized and shaped to engage the electrical junction box housing 110 to cover the open-face 134 of the open-face cavity 172. The cover plate 195 can be positioned over the open-face 134 after the electrical wires 116 are inserted within the apertures 136, 144, 146. This is typically the final step in the electrical wiring process. The electrical modular unit 114 can be formed as, for example, an electrical outlet or an electrical switch, adapted to electrically couple to electrical wires 116 within the inner housing 112. This gives the electrical modular unit 114 the modular application, or a component that is interchangeable with the junction box assembly, specifically the inner housing 112. The modular aspect provides easy assembly and flexible use to all individuals, with or without electrical experience. Electrical coupling can occur by engaging the electrical conducting members 190 to corresponding electrical wires 116. The electrical modular unit 114 also mechanically couples to the inner housing 112 by physically connecting each of the plurality of electrical conducting members 190 to the corresponding electrical wire 116 via one of the plurality of openings 189.

Advantageously, providing an electrical modular unit 114 that couples to the inner housing 112 in accordance with the present invention allows for labor-saving and cost-efficient electrical wiring. After electrical wires 116 are inserted and retained within the inner housing 112 of the electrical junction box assembly 100, an unskilled laborer can quickly and easily connect the electrical modular unit 114 to the electrical junction box assembly 100 by, for example, plugging in the electrical modular unit 114 to the inner housing 112. This can significantly reduce the skilled labor time and costs required to electrically wire a building or a structure. Additionally, unskilled homeowners (or commercial building owners) that desire the ability to conveniently update their electrical units, such as, for example, light dimmers, switches, electrical outlets, and the like, without having to perform complicated rewiring, can simply obtain a new electrical modular unit 114, unplug the old electrical modular unit 114, and plug-in the new electrical modular unit 114. Homeowners can perform this without having to pay for an electrician or without having to risk injury or structural damage by attempting to rewire themselves.

Referring now primarily to FIGS. 1-3, the inner housing 112 can further include a wire retention device 175 adapted to retain the electrical wire 138 within the inner housing 112 for electrically coupling the electrical wire 138 to the electrical modular unit 114. In one embodiment, the wire retention device 175 can include a resilient member, such as, for example, a pair of spring-based L-shaped plates 177 opposing one another, each spring-based L-shaped plate 177 having an elongated planar section 176 generally vertically disposed within the substantially-enclosed cavity 170 of the inner housing 112 and an angled planar section 178 extending from the elongated planar section 176 at an acute downward angle with respect to the elongated planar section 176. The electrical wire 138 can be slideably received into the inner housing 112 via the first aperture 136 of the electrical junction box housing 110 and, subsequently, via one of the plurality of inner housing apertures 113. The electrical wire 138 is frictionally retained within the inner housing 112 for electrically coupling the electrical wire 138 to the electrical modular unit 114. In one embodiment, the electrical wire 138 can be pushed with a downward force 180 to engage opposing angled planar sections 178 of the wire retention device 175 such that the bare electrical terminal 118, e.g., metal wiring, is frictionally retained between the angled planar sections 178. Advantageously, the wire retention device 175 allows for a one-step fastening process whereby the user is merely required to push the electrical wire 138 within the first aperture 136 to snap-in the electrical wire 138 via the wire retention device 175. This feature eliminates the need to use screws, loops, soldering, or twisting of wires in order to secure wires for electrical coupling. In one embodiment, the electrical junction box assembly 100 can include an electrical guard 197. The electrical guard 197 is comprised of a non-conducting material, such as a non-conductive polymer material, and may be formed as an annular ring disposed on a top surface of the electrical junction box housing 110 and concentric with the first aperture 136 of the electrical junction box housing 110. The electrical guard 197 is operably configured to receive the electrical wire 138 therethrough and provide a non-conducting shield protecting the external environment 120 from any exposure to metal wiring of the bare electrical terminal 118 that may be disposed above the top surface of the electrical junction box housing 110.

In one embodiment, the inner housing 112 can be removably attached to the electrical junction box housing 110. An upper section of each of opposing inner housing walls 154 can include a notch 155, or projection disposed on an exterior surface thereof. The electrical junction box housing 110 can include a pair of arms 163 operably configured to lockingly engage the corresponding notches 155 on the inner housing walls 154. In one embodiment, each of the pair of arms 163 can be formed as an L-shaped arm, where a lower projection 165 of the L-shaped arm 163 abuts the notch 155 when the inner housing 112 and the electrical junction box housing 110 are in assembled configuration. In use, a user can grip the inner housing 112 and slidingly engage and snap the inner housing 112 to the electrical junction box housing 110. Either one or both of the notch 155 and the arm 163 is preferably constructed of a resilient material adapted to allow the inner housing 112 to be pressure snapped into locking engagement with the electrical junction box housing 110.

Referring now primarily to FIG. 4, another exemplary embodiment of a wire retention device 475 is illustrated. The wire retention device 475 includes an abutment member 490 and an abutment fastener 492. The abutment member 490 includes a base 494, an abutment arm 496 projecting upwardly from a surface of the base 494, and an insert 498 frictionally secured within a slot at an end of the abutment arm 496 proximate the electrical wire 138. The insert 498 is preferably comprised of a rigid material, such as, for example, steel and may be formed with a pointed end for securing the electrical wire 138. The abutment arm 496 is preferably made of a resilient or flexible and non-conducting material, such as, for example, plastic or other polymer material. The abutment fastener 492 can be formed as a screw, or any other fastener that can be used to secure the electrical wire 138 within an inner housing 412 of an electrical junction box assembly 400. The abutment fastener 492 can include a head member 491 and a tail member 493, where the tail member 493 is inserted within an abutment fastener opening 495 defined by the one of a plurality of junction box housing walls 422. In one embodiment, the head member 491 comprises a polymer material that is non-conducting. The abutment member 490 is preferably disposed at a position within a substantially-enclosed cavity 470 of the inner housing 412 such that insertion of the abutment fastener 492 via the abutment fastener opening 495 results in a distal end of the tail member 493 abutting the abutment arm 496 and applying a downward force that results in the abutment arm 496 flexing toward the bare electrical terminal 118 of the electrical wire 138. This frictionally retains the bare electrical terminal 118 between the insert 498 and an electrical contact 499 disposed on an opposite side of the bare electrical terminal 118. As is apparent in the partially-sectional view of FIG. 4, an exemplary embodiment electrical junction box assembly 100 is depicted where at least one of the plurality of junction box housing walls 422 is integral with an inner housing wall 454.

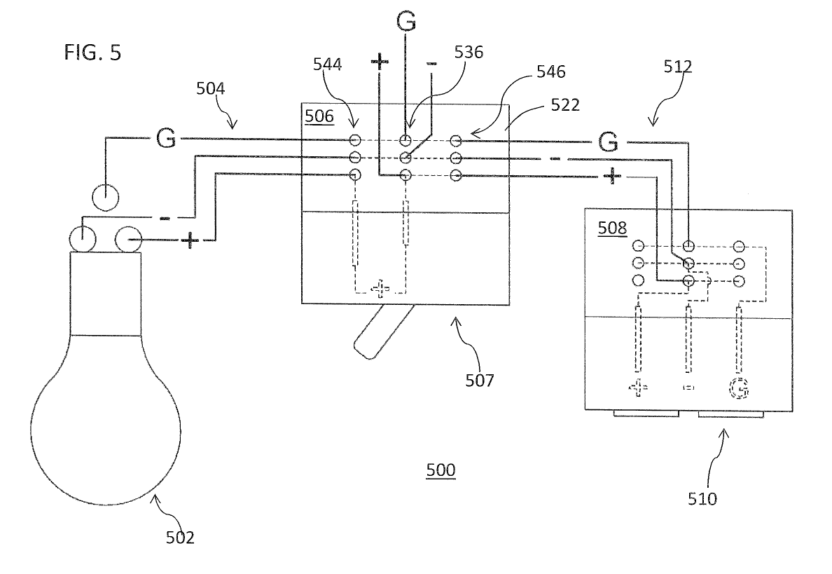

Referring now primarily to FIG. 5, an exemplary electrical circuit 500 in accordance with the present invention is illustrated in a schematic view. The electrical circuit 500 includes an electrical device 502, a first electrical junction box assembly 506 matingly engaged to a first electrical modular unit 507 formed as a light switch, and a second electrical junction box assembly 508 matingly engaged to a second electrical modular unit 510 formed as an electrical outlet. In the exemplary embodiment, the electrical device 502 is formed as a light fixture, however, the electrical device 502 can be any device that produces or is powered by electricity. The electrical device 502 is operably configured to receive a first set of electrical wires 504 from the first electrical junction box assembly 506. The first electrical junction box assembly 506 is operably configured to receive a second set of electrical wires 512 from the second electrical junction box assembly 508. As is apparent, providing apertures 536, 544, and 546 defined by a junction box housing wall 522 and dedicated to particular incoming and outgoing electrical lines provides clear organization and structure to a multitude of electrical wire sets 504, 512 that may be routed through several electrical junction boxes and electrical fixtures.

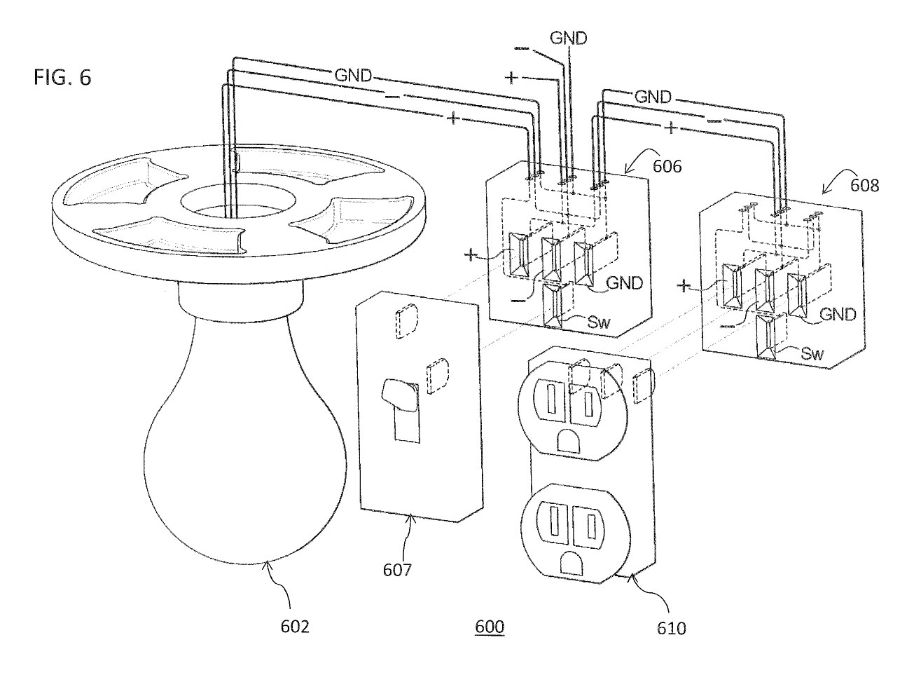

Referring now primarily to FIG. 6, another exemplary electrical circuit 600 in accordance with the present invention is presented in a schematic, partially expanded view. The electrical circuit 600 includes an electrical device 602, a first electrical junction box assembly 606 matingly engaged to a first electrical modular unit 607 formed as a light switch, and a second electrical junction box assembly 608 matingly engaged to a second electrical modular unit 610 formed as an electrical outlet.

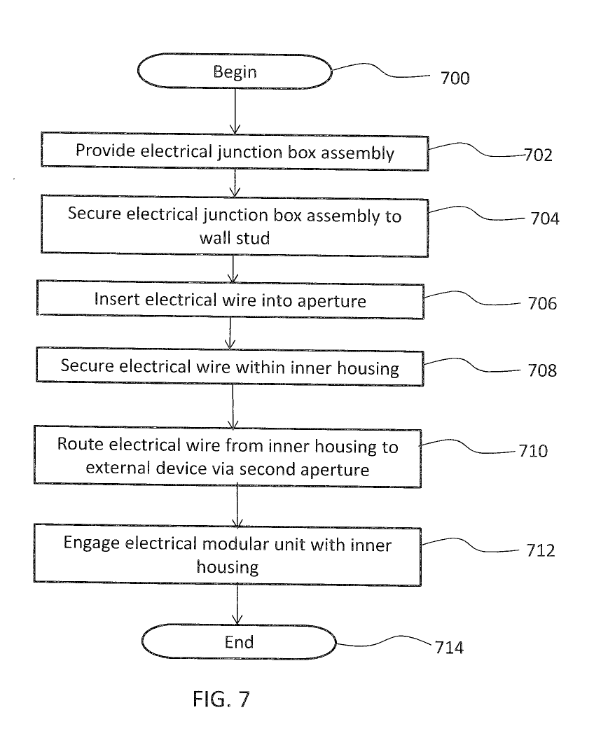

Referring now primarily to FIG. 7, a method of preparing electrical wiring within an electrical junction box without exposing any electrical wires therein to an external environment is provided in a flow diagram. The method begins at step 700 and immediately proceeds to step 702 where the electrical junction box assembly 100 is provided. In step 704, the user secures the electrical junction box housing 110 to the wall stud 193 laterally abutting the electrical junction box housing 110 by moving the fastener 191 from within the open-face cavity 172 through the fourth aperture 188 defined by at least one of the plurality of junction box walls 122 and fastening the fastener 191 to the wall stud 193. In step 706, the user inserts the electrical wire 138 that is electrically coupled to the circuit breaker 147 into the aperture 136 such that the electrical wire 138 is disposed only within the substantially-enclosed cavity 170 and not within the open-face cavity 172. In step 708, the user secures the electrical wire 138 within the inner housing 112. In one embodiment, the user secures the electrical wire 138 by slideably inserting the electrical wire 138 within the wire retention device 175 disposed within the inner housing 112. In another embodiment, the user secures the electrical wire 138 by fastening the electrical wire 138 with a screw. In yet another embodiment, the user secures the electrical wire 138 within the inner housing 112 by inserting the electrical wire 138 from the external environment 120 into the inner housing 112 via the aperture 136 in a singular vertical direction to engage a wire retention device disposed within the inner housing 112. In step 710, the user routes the second set of electrical wires 148 from the inner housing to an external electrical device 150 via the second aperture 144. The external electrical device 150 can be an electrical outlet, a light fixture, an electrical switch, and the like. In step 712, a user who may be unskilled as an electrician can matingly engage the electrical modular unit 114 to the inner housing 112 by, for example, simply plugging-in the electrical modular unit 114 to the inner housing 112. The process ends at step 714.

An electrical junction box assembly and method of use has been disclosed that facilitates electrical wiring within an electrical junction box that does not expose any electrical wires within the electrical junction box to the external environment and is operably configured to matingly engage an electrical modular unit via a simple process, such as a plug-in process, that reduces costs associated with skilled-electrician labor time.

What is claimed is:

1. An electrical junction box assembly, comprising:
an electrical junction box housing including:
a plurality of junction box walls defining an interior region, and
at least one aperture defined by at least one of the plurality of junction box walls, the at least one aperture adapted to receive at least one electrical wire; and
an inner housing:
disposed within the interior region of the electrical junction box housing;
including a plurality of inner housing walls;
including a plurality electrical contacts operably configured to couple with a corresponding electrical modular unit;
segmenting the interior region into:
a substantially-enclosed cavity, the substantially-enclosed cavity defined by the plurality of inner housing walls; and
an open-face cavity, the open-face cavity being a remainder of the interior region; and
substantially adjacent to one of the plurality of junction box walls such that the at least one electrical wire received into the electrical junction box housing through the at least one aperture is disposed only within the substantially-enclosed cavity and not within the open-face cavity.

2. The electrical junction box assembly in accordance with claim 1, wherein:
the inner housing is substantially adjacent to a top one of the plurality of junction box walls; and
the at least one aperture is defined by the top one of the plurality of junction box walls.

3. The electrical junction box assembly in accordance with claim 1, wherein the electrical junction box housing and the inner housing are integral with one another.

4. The electrical junction box assembly in accordance with claim 2 wherein the top one of the plurality of junction box walls is integral with a top one of the plurality of inner housing walls.

5. The electrical junction box assembly in accordance with claim 1, further comprising:
a second aperture defined by the at least one of the plurality of junction box walls, wherein the at least one aperture is operably configured to receive the at least one electrical wire from a circuit breaker into the inner housing and the second aperture is operably configured to route a second electrical wire from within the inner housing out to an external electrical device.

6. The electrical junction box assembly in accordance with claim 1, wherein the inner housing abuts the at least one of the plurality of junction box walls that defines the at least one aperture.

7. The electrical junction box assembly in accordance with claim 1, wherein the inner housing includes a wire retention device adapted to retain the at least one electrical wire within the inner housing for electrically coupling the at least one electrical wire to the corresponding electrical modular unit.

8. The electrical junction box assembly in accordance with claim 1, wherein the inner housing includes a wire retention device adapted to:
slideably receive the at least one electrical wire through the at least one aperture, and
frictionally retain the at least one electrical wire within the inner housing for electrically coupling the at least one electrical wire to the corresponding electrical modular unit.

9. The electrical junction box assembly in accordance with claim 1, wherein the wire retention device includes a resilient member.

10. The electrical junction box assembly in accordance with claim 1, wherein at least one of the plurality of junction box walls defines a second aperture operable as passageway from the open-face cavity to a wall stud in an external environment, the second aperture adapted to receive a fastener therethrough for fastening the electrical junction box housing to the wall stud laterally abutting the electrical junction box housing.

11. The electrical junction box assembly in accordance with claim 1, wherein the corresponding electrical modular unit includes an electrical conducting member and a front one of the plurality of inner housing walls defines at least one opening adapted to receive the electrical conducting member for electrically coupling the at least one electrical wire to the corresponding electrical modular unit.

12. The electrical junction box assembly in accordance with claim 1, wherein the corresponding electrical modular unit is formed as an electrical outlet adapted to electrically couple to the at least one electrical wire within the inner housing.

13. The electrical junction box assembly in accordance with claim 1, wherein the corresponding electrical modular unit includes an electrical conducting member and is formed as an electrical outlet adapted to electrically couple to the at least one electrical wire within the inner housing and mechanically couple to the inner housing by engaging the electrical conducting member of the electrical outlet to an opening defined by a front one of the plurality of inner housing walls.

14. The electrical junction box assembly in accordance with claim 13, wherein the electrical conducting member is formed as a projection.

15. The electrical junction box assembly in accordance with claim 1, wherein the corresponding electrical modular unit includes an electrical conducting member and is formed as an electrical switch adapted to electrically couple to the at least one electrical wire within the inner housing.

16. A method of preparing electrical wiring within an electrical junction box without exposing any electrical wires therein to an external environment, comprising:
providing an electrical junction box assembly including:
an electrical junction box housing having:
a plurality of junction box walls defining an interior region, and
at least one aperture defined by at least one of the plurality of junction box walls, and
an inner housing disposed within the interior region of the electrical junction box housing and segmenting the interior region into:
a substantially-enclosed cavity, and
an open-face cavity, the substantially-enclosed cavity defined by a plurality of inner housing walls forming the inner housing and the open-face cavity being a remainder of the interior region; and
inserting at least one electrical wire that is electrically coupled to a circuit breaker into the at least one aperture such that the at least one electrical wire is disposed only within the substantially-enclosed cavity and not within the open-face cavity.

17. The method in accordance with claim 16, further comprising:
slideably inserting the at least one electrical wire within a wire retention device disposed within the inner housing; and
securing the at least one electrical wire to the wire retention device.

18. The method in accordance with claim 16, further comprising:
inserting the at least one electrical wire from the external environment into the inner housing through the at least one aperture in a singular direction to engage a wire retention device disposed within the inner housing; and
securing the at least one electrical wire to the wire retention device.

19. The method in accordance with claim 16, further comprising:
receiving the at least one electrical wire from the circuit breaker into the inner housing through the at least one aperture; and
routing a second electrical wire from the inner housing to an external electrical device via a second aperture.

20. The method in accordance with claim 16, further comprising:
securing the electrical junction box housing to a wall stud laterally abutting the electrical junction box by moving a fastener from within the open-face cavity through a third aperture defined by at least one of the plurality of junction box walls and fastening the fastener to the wall stud.
